(19) United States
(12) Patent Application Publication
(10) Pub. No.: US 2009/0145747 A1
(43) Pub. Date: Jun. 11, 2009

(54) METHOD AND INSTALLATION FOR THE VACUUM COLOURING OF A METAL STRIP BY MEANS OF MAGNETRON SPUTTERING

(75) Inventors: Hugues CORNIL, Marchin (BE); Benoit Deweer, Sterrebeek (BE); Claude Maboge, Castillon (BE)

Correspondence Address: OBLON, SPIVAK, MCCLELLAND MAIER & NEUSTADT, P.C., 1940 DUKE STREET, ALEXANDRIA, VA, 22314, US

(73) Assignee: AcrelorMittal France, Saint Denis (FR)

(21) Appl. No.: 12/357,963

(22) Filed: Jan. 22, 2009

Related U.S. Application Data
(63) Continuation of application No. 12/092,709.

(30) Foreign Application Priority Data
Nov. 7, 2005 (EP) 05292355.4

(51) Int. Cl. C23C 14/35

(52) U.S. Cl. 204/192.32; 204/298.37

(57) ABSTRACT

A magnetron sputtering method for vacuum coloring a metal strip passing above at least one conductive counter electrode in a vacuum chamber. The method creates a plasma in a gas close to the metal strip, such as to generate radicals and/or ions that act on the strip, a magnetic confinement circuit being positioned above the strip. The counter electrode includes a mobile surface that can move in rotation and/or translation in relation to the metal strip, the surface being moved during the coloring process and being continuously cleaned by a cleaning device that is obscured from the plasma before being exposed once again to the plasma. A coloring installation can implement the method.

The present invention relates to a method and an installation for vacuum brightening, by magnetron sputtering, of a metal strip, such as a steel strip, for example.

During vacuum coating operations on a steel strip, the state of cleanness of the strip prior to deposition is one of the key factors for success, because it determines the good adherence of the coating to be deposited. One of the methods used to achieve this is vacuum brightening by magnetron sputtering, also known as etching. This method consists in creating a plasma between the strip and a counter electrode in a gas making it possible to generate radicals and/or ions. Under normal operating conditions, these ions will be accelerated toward the surface of the strip to be descaled and will tear off surface atoms, thus cleaning the surface, which may be soiled, activating it at the same time.

The strip to be descaled is moved opposite a counter electrode in a vacuum chamber. This electrode is polarized positively relative to the metal strip, itself is preferably grounded. A set of magnets positioned behind the strip confines the created plasma in the proximity thereof. In order to position the metal strip to be treated very precisely relative to the counter electrode needed for implementation of magnetron sputtering, the metal strip is generally disposed on a support roll, which can be rotated around its axis. However, this type of roll is not necessary for treatment of metal strips in the form of rigid plates.

The problem encountered during application of this technique for cleaning a metal strip such as a continuously traveling steel strip, however, is fouling of the counter electrode. During the brightening process, the particles eroded from the surface of the strip become deposited on the opposite parts, or in other words on the counter electrode, in time covering it with a poorly adhering black film. This ultimately cracks and peels, forming pulverulent cuttings that can initiate arcs. The formation of arcs can cause:
on the one hand, damage to the surface of the steel strip at the point where the arc was initiated,
on the other hand, a lack of brightening over a small area of the traveling strip, because of brief interruption (approximately 100 μs) of the power supply by the generator during detection of the arc.

Finally, when it is dielectric, the deposit can insulate the electrode and interfere with the functioning of the plasma.

It therefore proves indispensable to maintain a good state of cleanness of the counter electrode during the brightening process.

There is known European Patent A 0908535, which describes a method for descaling the surface of a metal strip contaminated by a thin oxide layer. The counter electrodes employed are used in pairs connected to an a.c. generator. They have flat or rounded shape, and they make it possible to prevent the formation of arcs for a certain time. These electrodes become fouled after they have been in service for a certain duration, thus making it necessary to interrupt the process to clean them or else to reduce the brightening power, thus detracting in every way from the efficacy and/or quality of brightening.

The objective of the present invention is therefore to remedy the disadvantages of the prior art by providing a method and an installation for vacuum brightening, by magnetron sputtering, of the surface of a traveling metal strip, thus making it possible to improve the quality and efficacy of brightening while avoiding any damage to the metal strip and any lack of brightening due to the untimely formation of electric arcs, and doing so without interruption of the process.

To this end, the invention has as its first object a method of vacuum brightening, by magnetron sputtering, of a metal strip traveling above at least one counter electrode of conductive material in a vacuum chamber, in which a plasma is created in a gas in proximity to the said metal strip, in such a way as to generate radicals and/or ions that act on this metal strip, a magnetic confinement circuit being positioned above the metal strip, wherein the counter electrode has a surface that can move in rotation and/or translation relative to the said metal strip, the surface being moved during brightening and being cleaned continuously by a cleaning device positioned in the shadow of the plasma before being reexposed to the plasma.

The method according to the invention can additionally incorporate the following characteristics, taken individually or in combination:
the cleaning device is a cleaning device with localized mechanical action.
the cleaning device is composed of a rigid scraper blade in contact with the moving surface of the counter electrode.
the materials detached from the moving surface of the counter electrode by the action of the cleaning device are recovered by means of a collection device positioned in the lower portion of the said vacuum chamber.
the counter electrode is polarized positively relative to the metal strip, and the metal strip may or may not be connected to ground.
the counter electrode is subjected to an alternating potential, and the metal strip may or may not be connected to ground.
the vacuum chamber is equipped with a counter electrode composed of at least two rotary cylinders and of a belt maintained tautly on the cylinders.
the counter electrode or electrodes is or are cooled.

A second object of the invention is composed of an installation for vacuum brightening, by magnetron sputtering, of a metal strip, comprising a vacuum chamber within which there is at least one counter electrode, means for polarizing the metal strip, means for polarizing the counter electrode, means making it possible to create a plasma in a gas between the metal strip and the counter electrode, at least one magnetic confinement circuit being positioned above the metal strip, and the counter electrode having a surface that can move in rotation and/or translation relative to the metal strip, as well as a device, positioned in the shadow of the plasma, for cleaning the moving surface.

The installation according to the invention can additionally incorporate the following characteristics, taken individually or in combination:
the cleaning device is a cleaning device with localized mechanical action,
the cleaning device is composed of a rigid scraper blade in contact with the moving surface of the counter electrode,
the vacuum chamber additionally comprises a device for collection of the materials detached from the moving surface of the counter electrode by the action of the cleaning device, the collection device being positioned in the lower portion of the said vacuum chamber,
the counter electrode is polarized positively relative to the metal strip, and the said metal strip may or may not be connected to ground,
the counter electrode is subjected to an alternating potential, and the metal strip may or may not be connected to ground,
the vacuum chamber is equipped with a counter electrode composed of at least two rotary cylinders and of a belt maintained tautly on the cylinders,
the counter electrode is equipped with cooling means.

The invention will now be described in more detail with reference to the attached figures, which represent:

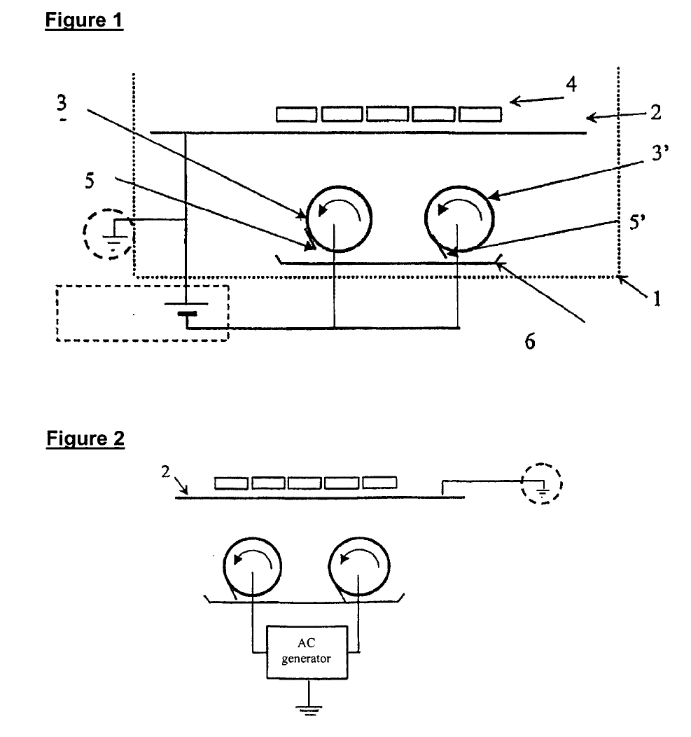

FIG. 1: a schematic cross-sectional view of one embodiment of an installation according to the invention,

FIG. 2: a schematic cross-sectional view of a second embodiment of an installation according to the invention,

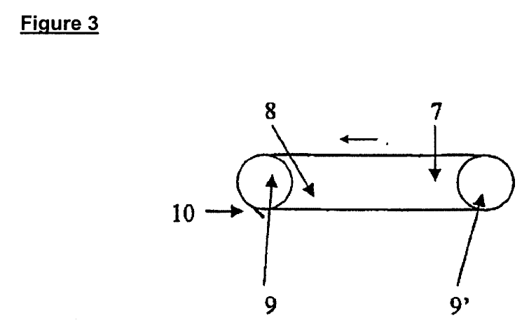

FIG. 3: a schematic cross-sectional view of a third embodiment of an installation according to the invention.

Referring first to FIG. 1, there can be seen therein a vacuum chamber 1, in the interior of which there travels a metal strip 2, such as a steel strip. In the lower part of this vacuum chamber 1 there are two counter electrodes 3 and 3′ of cylindrical shape, which can be rotated around their axes. Counter electrodes 3, 3′ must be of conductive material. Although a ferromagnetic material may be suitable, it is advisable to use a non-ferromagnetic material in order to avoid perturbing the magnetic confinement of the plasma.

Counter electrodes 3, 3′ are subjected to heating which entails cooling them in certain cases. They are driven in rotation, for example mechanically by the travel of metal strip 2. Counter electrodes 3, 3′ may also be driven by an electric motor positioned in vacuum, a pneumatic motor a hydraulic motor, by a passage turning in vacuum.

Metal strip 2 is connected to ground, while counter electrodes 3, 3′ are polarized positively.

Above this strip 2 there is disposed a magnetic circuit 4, having the form of magnets which serve to confine the plasma in the proximity of metal strip 2.

Each counter electrode 3, 3′ is equipped with a scraper blade 5, 5′ positioned in the shadow of the plasma for brightening of metal strip 2. The fixation of scraper blades 5, 5′ must be implemented with particular care, in order to avoid creating a short circuit between counter electrodes 3, 3′ and the other mounting parts, even after metallization of the internal surfaces of the cell by the descaled conductive particles. Anti-metallization baffles can be disposed around the insulators. These baffles are situated between the wall of chamber 1 and scraper blades 5, 5′, in order to insulate them mutually. In this way the support of scraper blades does not become metallized, so any short circuit is prevented.

Scraper blades 5, 5′ can be made of any appropriate material, provided it is not conductive. In particular, they can be made of ceramic or glass.

Precautions may be taken additionally to ensure that scraper blades 5, 5′ do not project cuttings toward metal strip 2, even by ricochets.

Vacuum chamber 1 also comprises a trough 6 for recovery of materials detached by scraper blades 5, 5′.

When metal strip 2 is being brightened in vacuum chamber 1, counter electrodes 3, 3′ are made to turn with relatively slow movement, in such a way that they are continuously cleaned by means of scraper blades 5, 5′. The materials detached by these means fall into trough 6, which can be regularly emptied.

Referring now to FIG. 2, there can be seen therein a second embodiment of the invention, in which an alternating potential is applied to counter electrodes 3, 3′, and traveling metal strip 2 may or may not be connected to ground.

The system can be composed of one or more counter electrodes. As can be seen in the partial view of FIG. 4, counter electrode 7 can also be composed of a belt 8 maintained tautly between two cylinders 9, 9′ and driven according to the “conveyor belt” principle. A scraper blade 10 positioned in the shadow of the plasma permits the belt to be cleaned when it travels into vacuum chamber 1.

### Exemplary Embodiment

One indicator of the efficacy of a brightening system may be the maximum power that can be applied to the brightening cell without formation of arcs.

A test was therefore conducted in which this maximum power was measured for a traditional brightening cell and for a brightening cell such as represented in FIG. 1.

In this way it was possible to calculate that the maximum stable power over time of a brightening installation according to the invention represents more than double that of a traditional installation equipped with a plane and fixed counter electrode.

Since the rate of erosion of a metal strip by magnetron brightening is related to the applied power, the use of counter electrodes according to the invention makes it possible to double the brightening efficacy.

The system of counter electrodes presented in the foregoing remains clean in the course of time and prevents the creation of arcs from particles resulting from brightening of the surface of the metal strip or the problem of disappearing anodes.

1-17. (canceled)

18. A method of vacuum brightening, by magnetron sputtering, a metal strip traveling above at least one counter electrode of conductive material in a vacuum chamber, the method comprising:
creating a plasma in a gas in proximity to the metal strip, in such a way as to generate radicals and/or ions that act on the metal strip, a magnetic confinement circuit being positioned above the metal strip, wherein the counter electrode includes a surface that can move in rotation and/or translation relative to the metal strip, the surface being moved during brightening and being cleaned continuously by a cleaning device positioned in the shadow of the plasma before being reexposed to the plasma.

19. A method according to claim 18, wherein the cleaning device is a cleaning device with localized mechanical action.

20. A method according to claim 19, wherein the cleaning device includes a rigid scraper blade in contact with the moving surface of the counter electrode.

21. A method according to claim 18, wherein materials detached from the moving surface of the counter electrode by action of the cleaning device are recovered by collection device positioned in a lower portion of the vacuum chamber.

22. A method according to claim 18, wherein the counter electrode is polarized positively relative to the metal strip, and the metal strip may or may not be connected to ground.

23. A method according to claim 18, wherein the counter electrode is subjected to an alternating potential, and the metal strip may or may not be connected to ground.

24. A method according to claim 18, wherein the vacuum chamber includes a counter electrode including at least two rotary cylinders and a belt maintained tautly on the cylinders.

25. A method according to claim 18, wherein the counter electrode is cooled.

26. A method according to claim 18, wherein the metal strip is a steel strip.

27. An installation for vacuum brightening, by magnetron sputtering, a metal strip, comprising:
a vacuum chamber, within which there is at least one counter electrode, means for polarizing the metal strip, means for polarizing the counter electrode, means for creating a plasma in a gas between the metal strip and the counter electrode, at least one magnetic confinement circuit positioned above the metal strip, and the counter electrode including a surface that can move in rotation and/or translation relative to the metal strip, as well as a device, positioned in the shadow of the plasma, for cleaning the moving surface.

28. An installation according to claim 27, wherein the cleaning device is a cleaning device with localized mechanical action.

29. An installation according to claim 28, wherein the cleaning device includes a rigid scraper blade in contact with the moving surface of the counter electrode.

30. An installation according to claim 27, wherein the vacuum chamber additionally comprises a device for collection of materials detached from the moving surface of the counter electrode by the action of the cleaning device, the collection device being positioned in a lower portion of the vacuum chamber.

31. An installation according to claim 27, wherein the counter electrode is polarized positively relative to the metal strip, and the metal strip may or may not be connected to ground.

32. An installation according to claim 27, wherein the counter electrode is subjected to an alternating potential, and the metal strip may or may not be connected to ground.

33. An installation according to claim 27, wherein the vacuum chamber includes a counter electrode including at least two rotary cylinders and a belt maintained tautly on the cylinders.

34. An installation according to claim 27, wherein the counter electrode includes cooling means.
